(19) United States
(12) Patent Application Publication
(10) Pub. No.: US 2016/0072038 A1
(43) Pub. Date: Mar. 10, 2016

(54) THERMOELECTRIC CONVERSION ELEMENT

(71) Applicant: KABUSHIKI KAISHA TOSHIBA, Tokyo (JP)

(72) Inventors: Hiromi YUASA, Kawasaki (JP); Masaki KADO, Kamakura (JP)

(21) Appl. No.: 14/842,449

(22) Filed: Sep. 1, 2015

(30) Foreign Application Priority Data
Sep. 4, 2014 (JP) 2014-180207

(51) Int. Cl. H01L 37/00

(52) U.S. Cl. CPC H01L 37/00

(57) ABSTRACT

A thermoelectric conversion element comprises: a substrate; an insulating ferromagnetic layer provided on the substrate and having a magnetization fixed in one direction; and a nonmagnetic metal layer provided on the ferromagnetic layer. The substrate is configured from an organic type material whose thermal conductivity is not less than 0.15 W/Km and not more than 1.5 W/Km, whose Young's modulus is not less than 0.2 Gpa and not more than 7 Gpa, and whose film thickness is 100 μm or less.

### CROSS REFERENCE TO RELATED .APPLICATIONS

This application is based on and claims the benefit of priority from prior Japanese Patent Application No. 2014-180207, filed on Sep. 4, 2014, the entire contents of which are incorporated herein by reference.

### FIELD

Embodiments described in the present specification relate to a thermoelectric conversion element.

### BACKGROUND

A thermoelectric conversion element that utilizes a spin Seebeck effect to convert heat into a voltage, is known. A configuration in which an insulating ferromagnetic layer and a nonmagnetic metal layer are stacked in order on a substrate, is known as a general configuration of the thermoelectric conversion element. When a temperature gradient ΔT is applied to the ferromagnetic layer, a spin pressure which is a difference between an up-spin flow and a down-spin flow, is generated. This is called the spin Seebeck effect.

The spin pressure generated in the ferromagnetic layer is a flow of the difference between the up-spin flow and the down-spin flow, and is provided as a spin flow Jspin. When the spin flow Jspin flows, an electromotive force E is generated in a direction orthogonal to the spin flow Jspin and to a magnetization of the ferromagnetic layer, by an inverse spin Hall effect, and a current flows. As a result, electricity is generated by thermoelectric conversion.

Conventionally known as the substrate of the thermoelectric conversion element were a rigid type substrate employing the likes of silicon or glass, and a flexible type substrate employing a polyamide. However, the rigid type substrate had the problem of lacking flexibility and of being difficult to apply to devices of a wide variety of shapes including wearable devices. On the other hand, a polyimide substrate had the problem that although it does not matter in terms of flexibility, its power generation efficiency is low.

### BRIEF DESCRIPTION OF THE DRAWINGS

FIG. 1 is a block diagram showing a configuration of a thermoelectric conversion element according to a first embodiment.

FIG. 2 is a schematic view for explaining a principle related to power generation efficiency of the thermoelectric conversion element.

FIG. 3 is a table showing substrate materials of the thermoelectric conversion element.

FIG. 4 is a graph showing a relationship between the substrate material and a temperature difference applied to the ferromagnetic layer.

FIG. 5 is a graph showing a relationship between the substrate material and the power generation efficiency.

FIG. 6 is a graph showing a relationship between film thickness of the substrate and the temperature difference applied to the ferromagnetic layer.

FIG. 7 is a graph showing a relationship between film thickness of the substrate and power generation amount.

### DETAILED DESCRIPTION

An embodiment described in the present specification is a thermoelectric conversion element, comprising: a substrate; an insulating ferromagnetic layer provided on the substrate and having a magnetization fixed in one direction; and a nonmagnetic metal layer provided on the ferromagnetic layer. The substrate is configured from an organic type material whose thermal conductivity is not less than 0.15 W/Km and not more than 1.5 W/Km, whose Young's modulus is not less than 0.2 Gpa and not more than 7 Gpa, and whose film thickness is 100 μm or less.

A thermoelectric conversion element according to an embodiment of the present invention will be described below with reference to the drawings.

### First Embodiment

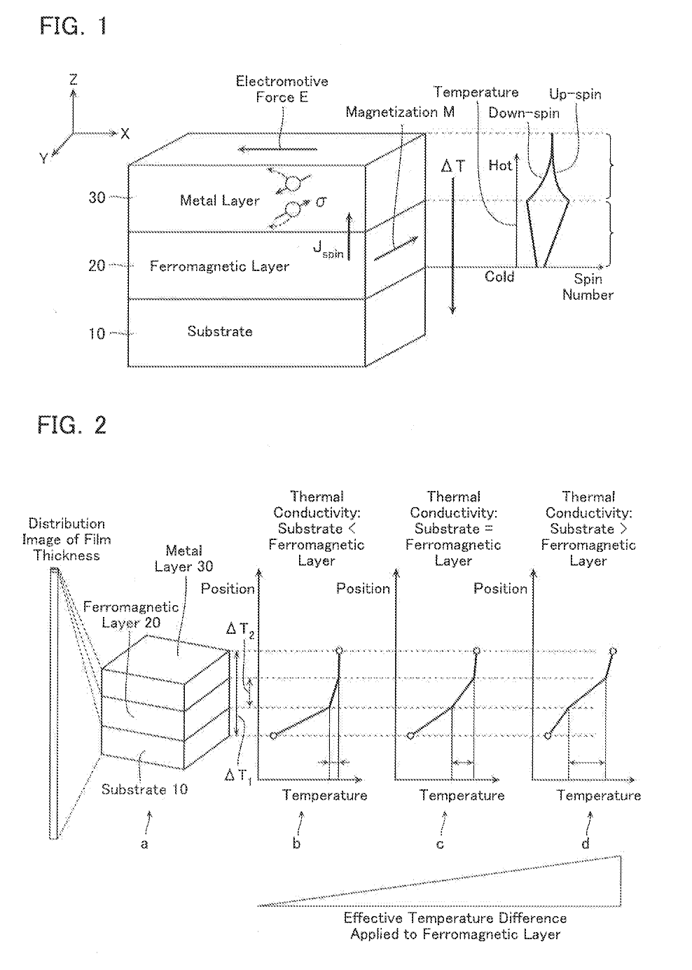

First, a basic configuration and operating principle of a thermoelectric conversion element according to a first embodiment will be described with reference to FIG. 1. The thermoelectric conversion element comprises an insulating ferromagnetic layer 20 and a nonmagnetic metal layer 30 stacked on a substrate 10. Below, a direction of the stacking (a direction normal to a surface of the substrate 10) will be referred to as a Z direction. The ferromagnetic layer 20 is provided with, for example, a magnetization M along a direction (a Y direction in FIG. 1) intersecting the Z direction. Terminals (not illustrated) for extracting a voltage are provided on the metal layer 30.

After a surface cleaning is performed on the substrate 10, the ferromagnetic layer 20 and the metal layer 30 can be deposited by employing the likes of: a dry process such as a sputtering method, a vapor deposition method, and a CVD method; a wet process such as an electroplating method or an electroless plating method; or a coating method. The substrate 10, the ferromagnetic layer 20, and the metal layer 30 may contact each other directly. However, it is also possible to adopt a configuration than sandwiches the likes of a buffer film or adhesive film between each of the layers.

Employable as a material of the ferromagnetic layer 20 is a ferrite material such as garnet ferrite, spinel ferrite, and hexagonal ferrite, or a stacked body of those materials. Employable as a material of the metal layer 30 is platinum (Pt), gold (Au), iridium (Ir), nickel (Ni), tantalum (Ta), tungsten (W), or chromium (Cr), or an alloy of these. A material of the substrate 10 will be mentioned in detail at a later stage.

Next, the operating principle of the thermoelectric conversion element will be described. When a temperature difference ΔT is provided along the Z direction, that is, the stacking direction, of the element, a difference occurs between the distribution of up-spin electrons and the distribution of down-spin electrons in the ferromagnetic layer 20 (refer to graph at upper right of FIG. 1). This phenomenon is called a spin Seebeck effect, and the difference between the distribution of up-spin electrons and the distribution of down-spin electrons occurring at this time is called a spin pressure. The spin pressure generated within the ferromagnetic layer 20 is transmitted to the metal layer 30 as a spin flow Jspin. The spin flow Jspin is a flow caused by the difference between the distribution of the up-spin electrons and the distribution of the down-spin electrons, and is not a flow of charge.

When the spin flow Jspin is transmitted to inside the metal layer 30, an inverse spin Hall effect causes a current which is a flow of charge to flow in a direction (an X direction in FIG. 1) orthogonal to the spin flow Jspin and to the magnetization M of the ferromagnetic layer 20, and an electromotive force E is generated. This electromotive force E causes the thermoelectric conversion element to generate power and function as an electrical energy source.

Next, a way of applying the temperature difference ΔT in the thermoelectric conversion element will be described with reference to FIG. 2. As shown in FIG. 2(a), when the thermoelectric conversion element is placed in a certain environment, a temperature difference ΔT applied due to the environment is equal to a temperature difference between an upper surface and a lower surface of the thermoelectric conversion element. In this temperature difference, a temperature difference contributing to power generation is only a temperature difference ΔT2 between an upper surface and a lower surface of the ferromagnetic layer 20 that exerts the spin Seebeck effect. Therefore, distributing to ΔT2 as large an amount of temperature difference of ΔT1 as possible makes it possible to raise power generation efficiency under an identical environment.

Now, when ΔT1 is fixed by the environment, the distribution of temperature difference including ΔT2 is determined by thermal conductivity k and thickness t in each of layers of the substrate 10, the ferromagnetic layer 20, and the metal layer 30. As shown in a distribution image of film thickness in FIG. 2(a), a thickness of the metal layer 30 (for example, 10 nm) is smaller compared to a thickness of the substrate 10 (for example, 10 μm) and a thickness of the ferromagnetic layer 20 (for example, 100 nm). Furthermore, considering that thermal conductivity of the metal layer 30 is large compared to that of the substrate 10 and the ferromagnetic layer 20, the temperature difference distributed to the metal layer 30 is extremely small, and may be ignored for the purpose of calculation. Accordingly, ΔT2 can be expressed as follows.

[Mathematical Expression 1]

ΔT/2/ΔT1=(t_{(ferromagnetic layer)}/k_{(ferromagnetic layer)})/t_{(substrate)}/k_{(substrate)}) Expression 1

It is therefore found that the larger is the thermal conductivity k of the substrate 10 and the smaller is the thickness t of the substrate 10 (more precisely, the smaller is a film thickness ratio of the substrate 10 to the ferromagnetic layer 20), the larger becomes the temperature difference ΔT2 distributed to the ferromagnetic layer 20.

FIGS. 2(b) to 2(d) are graphs showing a relationship between a position and temperature within the thermoelectric conversion element in the case where film thickness ratios of the substrate 10, the ferromagnetic layer 20, and the metal layer 30 are set constant and a relationship of thermal conductivities k of the substrate 10 and the ferromagnetic layer 20 is changed. Here, a metal layer 30 side is high temperature, and a substrate 10 side is low temperature. As shown in FIGS. 2(b) to 2(d), it is found that the larger is the thermal conductivity of the substrate 10, the larger becomes the effective temperature difference ΔT2 applied to both ends of the ferromagnetic layer 20.

Next, power generation efficiency is calculated based on the temperature difference ΔT2 calculated by Expression 1. First, thermo-electromotive force V in the ferromagnetic layer 20 is given by the following expression.

[Mathematical Expression 2]

V=S×ΔT2 Expression 2

Now, S is a substance-specific spin Seebeck coefficient.

Furthermore, power generation efficiency per unit area P is given by the following expression.

[Mathematical Expression 3]

P=0.25×(R×V²)/(L×w) Expression 3

Now, R is internal resistance of the metal layer 30, and L×w is cross-sectional area of the thermoelectric conversion element (product of width L and depth w). It is found from Expressions 2 and 3 that the larger is the temperature difference ΔT2 applied to the ferromagnetic layer 20, the more power generation efficiency P increases.

Conventionally, in research and development for improving power generation efficiency of the thermoelectric conversion element, the likes of material selection or improvement of shape in the ferromagnetic layer 20 that exerts the spin Seebeck effect was the mainstream, and not so much attention had been paid to the likes of material or shape of the substrate 10. In contrast, the inventors involved in the present application discovered that, as mentioned above, the thermal conductivity k and thickness t of the substrate 10 contribute greatly to power generation efficiency of the thermoelectric conversion element. The finding is a finding first obtained by the inventors involved in the present application. A configuration of the substrate 10 utilizing the above-described finding will be further described in detail below.

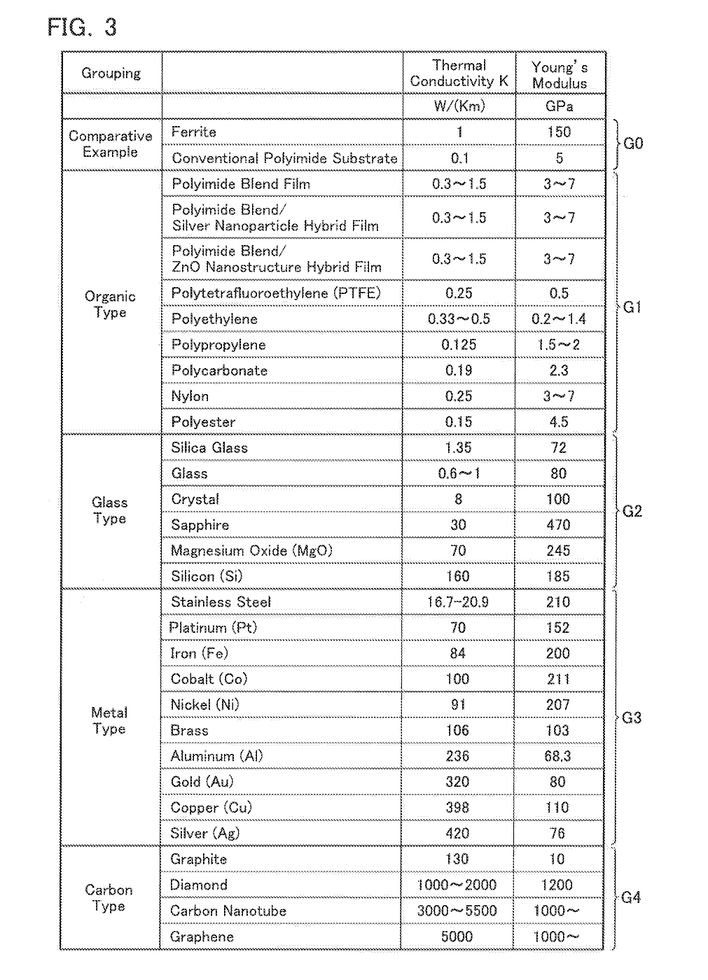

FIG. 3 is a table showing materials that can be used in the substrate 10, and thermal conductivity k and the Young's modulus of each of the materials. The materials are grouped into comparative example (G0), organic type (G1), glass type (G2), metal type (G3), and carbon type (G4) respectively. The unit, of thermal conductivity k is [W/(Km)], and the unit of the Young's modulus is [GPa].

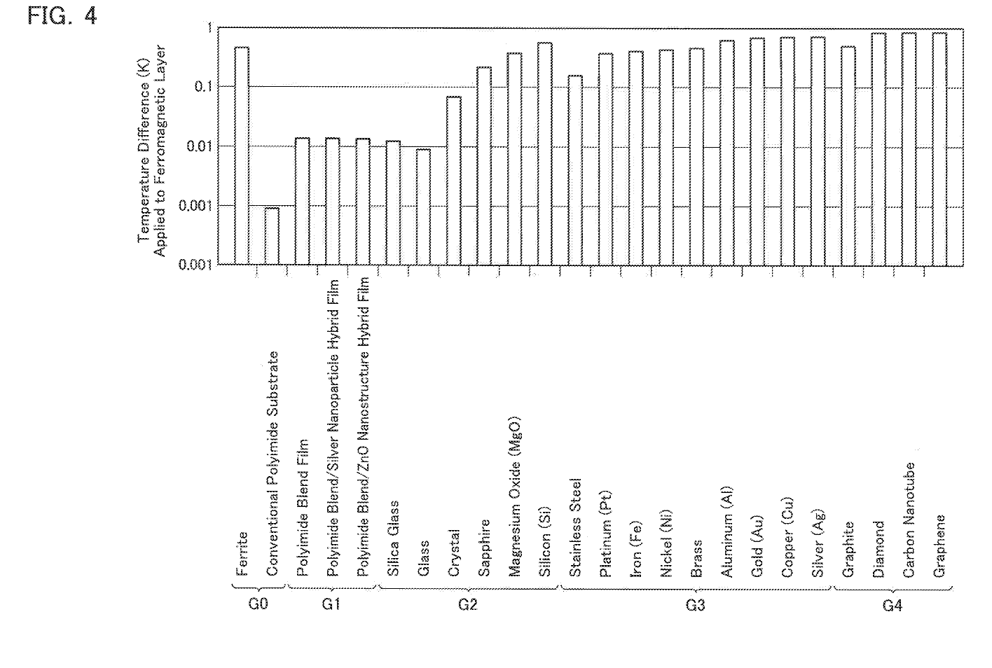

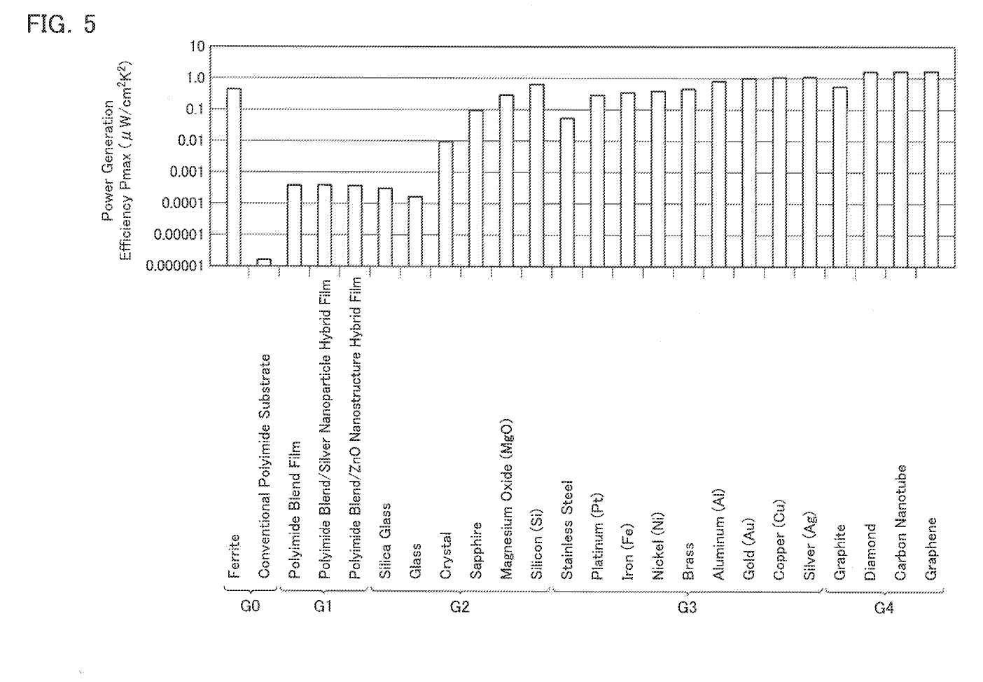

FIG. 4 is a graph that shows, in a form corresponding to each of the materials of FIG. 3, a simulation result of the temperature difference ΔT2 applied to the ferromagnetic layer 20 in the case where an environmental temperature difference (ΔT1 of FIG. 2) is set to 1 K (refer to Expressions 1 to 2). Moreover, FIG. 5 is a graph that shows, in a form corresponding to each of the materials of FIG. 3, a simulation result of power generation efficiency in the case where the environmental temperature difference ΔT1 is set to 1 K (refer to Expressions 1 to 3).

As conditions of the simulation, the spin Seebeck coefficient S was set to 100 [μV/Km], and the internal resistance R of the metal layer 30 was set to 270Ω (in the case of using platinum (Pt)). In addition, regarding cross-sectional area of the thermoelectric conversion element which is a sample, a length L in the X direction that the thermo-electromotive force is generated was set to 0.6 mm, and a length w in the Y direction that magnetization in the ferromagnetic layer 20 acts was set to 0.2 mm. Moreover, film thickness of the substrate 10 was set to 10 μm, and film thickness of the ferromagnetic layer 20 was set to 100 nm.

The thermoelectric conversion element according to the present embodiment has an object of providing a thermoelectric conversion element that combines both flexibility and a high power generation efficiency, and for the above-described reasons explained by FIGS. 2(a) to 2(d), the higher is the thermal conductivity k of a material, the easier it is to achieve high power generation efficiency. However, as explained by Expressions 1 to 3, reducing the film thickness of the substrate 10 makes it possible to increase the temperature difference ΔT2 applied to the ferromagnetic layer 20 and improve power generation efficiency, even for a material whose thermal conductivity k is low.

On the other hand, regarding flexibility, the lower is the Young's modulus of a material, the more easily can be achieved a device which is soft and highly flexible. However, reducing the film thickness of the substrate 10 makes it possible to raise flexibility, even for a material whose Young's modulus is high. Below, substrate materials according to a comparative example will be described, and then material characteristics and an appropriate film thickness for combining both flexibility and high power generation efficiency for each of the groups will be described respectively.

Group G0 according to the comparative example shows: ferrite (thermal conductivity k=1 [W/(Km)], Young's modulus=150 [GPa]) which is a conventionally known material of a rigid substrate; and polyimide (thermal conductivity k=0.1 [W/(Km)], Young's modulus=5 [GPa]) which is a conventionally known material of a flexible substrate. The rigid substrate has a higher thermal conductivity k compared to a polyimide substrate, but has a problem that its Young's modulus is large and its flexibility is poor. On the other hand, the polyimide substrate, although being more excellent in flexibility compared to the rigid substrate, has a problem that its thermal conductivity is extremely small and its power generation efficiency is poor. In this way, it is difficult for flexibility and high power generation efficiency to be combined in the substrate materials according to the comparative example.

Group G1 of the present embodiment is organic type materials whose thermal conductivity k [W/(Km)] is in a range of not less than 0.15 and not more than 1.5 and whose Young's modulus [GPa] is in a range of not less than 0.2 and not more than 7. Of the materials included in the first group G1, the three kinds of materials of a polyimide type shown in upper rows (polyimide blend film, polyimide blend/silver nanoparticle hybrid film, and polyimide blend/ZnO nanostructure hybrid film) are characterized in having higher thermal conductivity compared to a conventional polyimide substrate (refer to group G0) by adding a certain material to polyimide.

Now, a polyimide blend film is a material in which a single polyimide has some kind of particle (for example, simple substance or compound including a metal element) mixed therein. The mixed-in material may include the likes of ZnO or Ag, for example. For example, a ZnO polyimide blend having ZnO blended, therein can be obtained by compounding needle-shaped ZnO particles as a filler in sBPDA-SDA(SD) acting as a sulfur-containing polyimide and sBPDA-TFDB(TF) acting as a fluorine-containing polyimide. In more detail, the ZnO particles are dispersed in a solution of polyamic acid (PAA) which is a polyimide precursor, this then being applied on a Si substrate by spin coating and dried, then heated at approximately 350° C. under a nitrogen flow to be thermally imidized. As a result, a single polyimide thin film and a polyimide blend thin film are produced (refer to Society of Polymer Science Proceedings, Vol. 57, No. 1 (2008), p. 646). Furthermore, superimposing silver nanoparticles or ZnO nanostructures, for example, on the above-described polyimide blend film makes it possible to obtain a hybrid film whose thermal conductivity is further raised. (Takezawa Yoshitaka [editorial supervisor], “Advanced Composites Having High Thermal Conductivities”, CMC Books, published January 2011).

Moreover, group G1 includes polytetrafluoroethylene (PTFE), polyethylene, polypropylene, polycarbonate, nylon, and polyester, as well as the above-described polyimide type materials.

The substrate materials shown in group G1 have characteristics of overall having a Young's modulus which is low and being excellent in flexibility. At the same time, with regard also to their thermal conductivity k, they have a higher value (k≧0.15) compared to that (k=0.1) of the conventional polyimide substrate of the comparative example. Therefore, the temperature difference ΔT2 applied to the ferromagnetic layer 20 increases more compared to in the comparative example (refer to FIG. 4), and power generation efficiency also improves by a double-digit or more compared to in the comparative example (refer to FIG. 5). As a result, it becomes possible to combine both flexibility and high power generation efficiency. However, as will be mentioned below, in order to achieve an even higher power generation efficiency, it is preferable to reduce the film thickness of the substrate 10 or a film thickness ratio of the substrate 10 to the ferromagnetic layer 20 to increase the temperature difference ΔT2 applied to the ferromagnetic layer 20.

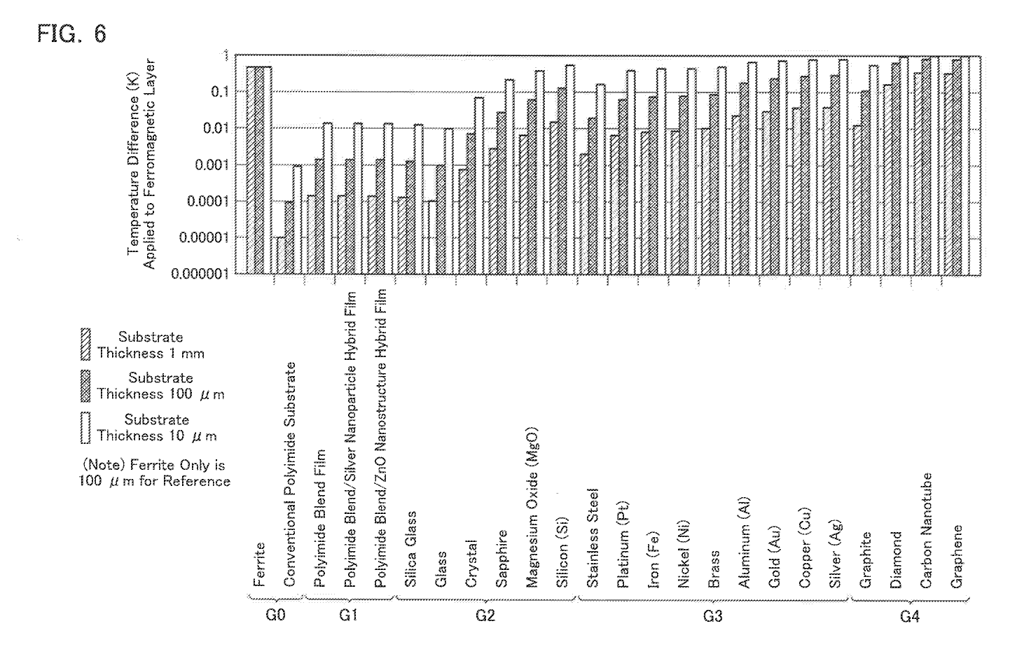

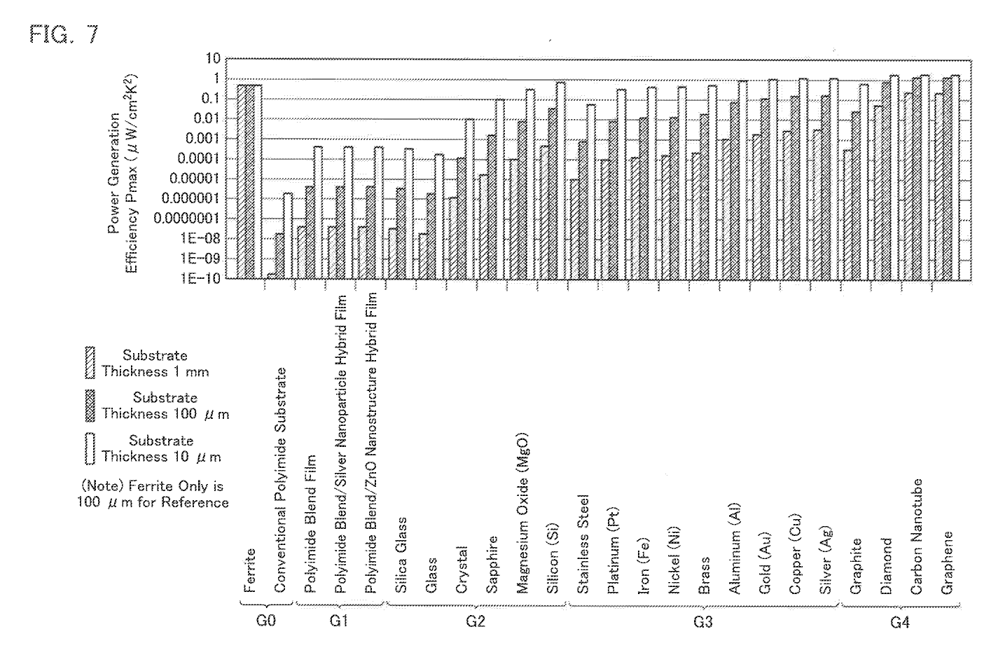

FIG. 6 is a graph showing the temperature difference ΔT2 applied to the ferromagnetic layer 20 when the film thickness of the substrate 10 is changed between 1 mm, 100 μm, and 10 μm. FIG. 7 is a graph showing the power generation efficiency when the film thickness of the substrate 10 is changed by a same method in FIG. 6. In FIGS. 6 and 7, the film thickness of the ferromagnetic layer 20 is calculated as 100 nm.

As shown in FIGS. 6 and 7, as the film thickness of the substrate 10 increases, the temperature difference ΔT2 applied to the ferromagnetic layer 20 decreases, as a result of which a power generation amount also decreases. A reduction amount of the power generation amount is extremely large particularly in the substrate materials of group G1 whose thermal conductivity is low. Therefore, in order to secure a power generation amount of at least 10⁻⁶ (μW/cm²K²) or more when employing the substrate materials of group G1, the film thickness of the substrate 10 is preferably 100 μm or less, and more preferably 10 μm or less. In other words, the film thickness ratio of the substrate 10 to the ferromagnetic layer 20 is preferably 1,000 or less, and more preferably 100 or less.

Next, group G2 of the present embodiment is glass type materials whose thermal, conductivity k [W/(Km)] is in a range of not less than 0.6 and not more than 160 and whose Young's modulus [GPa] is in a range of not less than 72 and not more than 470. Group G2 includes silica glass, glass, crystal, sapphire, magnesium oxide (MgO), and silicon (Si).

The substrate materials shown in group G2 have a higher thermal conductivity (k≧0.6) compared to those of group G1. Therefore, the temperature difference ΔT2 applied to the ferromagnetic layer 20 increases even more compared to in group G1 (refer to FIG. 4), and power generation efficiency also improves even more compared to in group G1 (refer to FIG. 5). On the other hand, the Young's modulus is comparatively large, hence in order to combine power generation efficiency also with flexibility, the film thickness of the substrate 10 is preferably set to a certain amount or less. Specifically, the film thickness of the substrate 10 is preferably 1 mm or less, and more preferably 100 μm or less.

Moreover, as shown in FIGS. 6 and 7, the decrease amounts of the temperature difference ΔT2 and of the power generation amount accompanying an increase in film thickness of the substrate 10 are still large. Therefore, in order to secure a power generation amount of at least 10⁻⁶ (μW/cm²K²) or more, the film thickness of the substrate 10 is preferably 500 μm or less, and more preferably 50 μm or less. In other words, the film thickness ratio of the substrate 10 to the ferromagnetic layer 20 is preferably 5,000 or less, and more preferably 500 or less.

Next, group G3 of the present embodiment is metal type materials whose thermal, conductivity k [W/(Km)] is in a range of not less than 16.7 and not more than 420 and whose Young's modulus [GPa] is in a range of not less than 76 and not more than 211. Group G3 includes stainless steel, platinum (Pt), iron (Fe), cobalt (Co), nickel (Ni), brass, aluminum (Al), gold (Au), silver (Ag), and copper (Cu).

The substrate materials shown in group G3 have an even higher thermal conductivity (k≧16.7) compared to those of group G2. Therefore, the temperature difference ΔT2 applied to the ferromagnetic layer 20 increases even more compared to in group G1 and group G2 (refer to FIG. 4), and power generation efficiency also improves even more compared to in group G1 and group G2 (refer to FIG. 5). On the other hand, the Young's modulus is comparatively large, hence in order to combine power generation efficiency also with flexibility, the film thickness of the substrate 10 is preferably set to a certain amount or less. Specifically, the film thickness of the substrate 10 is preferably 100 μm or less, and more preferably 10 μm or less.

Moreover, as shown in FIGS. 6 and 7, the decrease amounts of the temperature difference ΔT2 and of the power generation amount accompanying an increase in film thickness of the substrate 10 are more suppressed, compared to in group G1 and group G2. Therefore, in order to secure a power generation amount of at least 10⁻⁶ (μW/cm²K²) or more, the film thickness of the substrate 10 is preferably 1 mm or less, and more preferably 100 μm or less. In other words, the film thickness ratio of the substrate 10 to the ferromagnetic layer 20 is preferably 10,000 or less, and more preferably 1,000 or less.

Next, group G4 of the present embodiment is carbon type materials whose thermal conductivity k [W/(Km)] is in a range of not less than 130 and not more than 5500 and whose Young's modulus [GPa] is in a range of not less than 10 and not more than 1200. Group G4 includes graphite, diamond, a carbon nanotube, and graphene.

The substrate materials shown in group G4 have the highest thermal conductivity (k≧130) of all of the groups. Therefore, the temperature difference ΔT2 applied to the ferromagnetic layer 20 increases even more compared to in group G1 through group G3 (refer to FIG. 4), and power generation efficiency also improves even more compared to in group G1 through group G3 (refer to FIG. 5). On the other hand, the Young's modulus also is the largest of all of the groups, and in order to combine power generation efficiency also with flexibility, the film thickness of the substrate 10 is preferably set to a certain amount or less. Specifically, the film thickness of the substrate 10 is preferably 100 μm or less, and more preferably 10 μm or less.

Moreover, as shown in FIGS. 6 and 7, the decrease amounts of the temperature difference ΔT2 and of the power generation amount accompanying an increase in film thickness of the substrate 10 are significantly suppressed compared to in groups G1 through G3. Therefore, a sufficient power generation amount can be secured, when film thickness is in a range (100 μm or less) which is preferable from the above-mentioned viewpoint of flexibility.

### Other Embodiments

While certain embodiments of the present inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A thermoelectric conversion element, comprising:
a substrate;
an insulating ferromagnetic layer provided on the substrate and having a magnetization fixed in one direction; and
a nonmagnetic metal layer provided on the ferromagnetic layer,
the substrate being configured, from an organic type material whose thermal conductivity is not less than 0.15 W/Km and not more than 1.6 W/Km, whose Young's modulus is not less than 0.2 Gpa and not more than 7 Gpa, and whose film thickness is 100 μm or less.

2. The element according to claim 1, wherein
the film thickness of the substrate is 10 μm or less.

3. The element according to claim 1, wherein
a film thickness ratio of the substrate to the ferromagnetic layer is 1,000 or less.

4. The element according to claim 1, wherein
a film thickness ratio of the substrate to the ferromagnetic layer is 100 or less.

5. The element according to claim 1, wherein
the organic type material includes any of: a polyimide blend including simple substance or compound of a metal element; polytetrafluoroethylene; polyethylene; polypropylene; a polycarbonate; nylon; and a polyester.

6. A thermoelectric conversion element, comprising:
a substrate;
an insulating ferromagnetic layer provided on the substrate and having a magnetization fixed in one direction; and
a nonmagnetic metal layer provided on the ferromagnetic layer,
the substrate being configured from a glass type material whose thermal conductivity is not less than 0.6 W/Km and not more than 160 W/Km, whose Young's modulus is not less than 72 Gpa and not more than 470 Gpa, and whose film thickness is 500 μm or less.

7. The element according to claim 6, wherein
the film thickness of the substrate is 50 μm or less.

8. The element according to claim 6, wherein
a film thickness ratio of the substrate to the ferromagnetic layer is 5,000 or less.

9. The element according to claim 6, wherein
a film thickness ratio of the substrate to the ferromagnetic layer is 500 or less.

10. The element according to claim 6, wherein
the glass type material includes any of: silica glass; glass; crystal; sapphire; magnesium oxide; and silicon.

11. A thermoelectric conversion element, comprising:
a substrate;
an insulating ferromagnetic layer provided on the substrate and having a magnetization fixed in one direction; and
a nonmagnetic metal layer provided on the ferromagnetic layer,
the substrate being configured from a metal type material whose thermal conductivity is not less than 16.7 W/Km and not more than 420 W/Km, whose Young's modulus is not less than 76 Gpa and not more than 211 Gpa, and whose film thickness is 1 mm or less.

12. The element according to claim 11, wherein
the film thickness of the substrate is 100 μm or less.

13. The element according to claim 11, wherein
a film thickness ratio of the substrate to the ferromagnetic layer is 10,000 or less.

14. The element according to claim 11, wherein
a film thickness ratio of the substrate to the ferromagnetic layer is 1,000 or less.

15. The element according to claim 11, wherein
the metal type material includes any of: stainless steel; platinum; iron; cobalt; nickel; brass; aluminum; gold; silver; and copper.

16. A thermoelectric conversion element, comprising:
a substrate;
an insulating ferromagnetic layer provided on the substrate and having a magnetization fixed in one direction; and
a nonmagnetic metal layer provided on the ferromagnetic layer,
the substrate being configured from a carbon type material whose thermal conductivity is not less than 130 W/Km and not more than 5500 W/Km, whose Young's modulus is not less than 10 Gpa and not more than 1200 Gpa, and whose film thickness is 100 μm or less.

17. The element according to claim 16, wherein
the film thickness of the substrate is 10 μm or less.

18. The element according to claim 16, wherein
the carbon type material includes any of: graphite; diamond; a carbon nanotube; and graphene.
